(19) United States
(12) Patent Application Publication
(10) Pub. No.: US 2006/0223240 A1
(43) Pub. Date: Oct. 5, 2006

(54) Method of making substrate for integrated circuit

(75) Inventor: Hsin-Chen Yang, Taichung County (TW)

Correspondence Address: BROWDY AND NEIMARK, P.L.L.C.;624 NINTH STREET, NW, SUITE 300, WASHINGTON, DC, 20001-5303, US

(73) Assignee: Lingsen Precision Industries, Ltd., Taichung (TW)

(21) Appl. No.: 11/109,785

(22) Filed: Apr. 20, 2005

(30) Foreign Application Priority Data
Apr. 1, 2005 (TW) 94110642

(51) Int. Cl. H01L 21/56

(52) U.S. Cl. 438/127; 438/780; 438/700

(57) ABSTRACT

A method of making an IC substrate includes the steps of: a) preparing a substrate having a front side and a back side and half-etching the substrate to form a filling space in the front side of the substrate subject to a predetermined depth and area, b) putting the substrate thus obtained from step a) in a cavity of a mold and employing a polymer filling and mold pressing procedure to fill up the filling space with an insulative polymer, and c) removing the substrate from the mold and half-etching the back side of the substrate body so as to obtain an IC substrate.

### BACKGROUND OF THE INVENTION

1. Field of the Invention

The present invention relates to substrates for integrated circuit (IC) and more particularly, to a method of making a substrate of an IC.

2. Description of the Related Art

Following fast development of technology, it has become the market trend to provide electronic products having lighter, thinner, shorter and smaller characteristics. To fit this market trend, high-performance ICs are developed. From early metal lead frame package technology to current flip chip technology, fabrication of IC substrates has been continuously improved. The invention pertains to improvement on the fabrication of QFN (Quad Flat No-lead) IC substrates.

A prior art QFN IC substrate fabrication method is known including the steps of (a) half-etching a substrate to form a filling space at the front side of the substrate subject to a predetermined depth and area, (b) placing the substrate on a platform and then applying a fluid of insulative polymer to the substrate and then moving a scraper over the surface of the substrate to have the filling space of the substrate be filled up with the insulative polymer.

According to the aforesaid IC substrate fabrication method, there is a strict limitation to the type of the insulative polymer used. The substrate may curve significantly after filling of the insulative polymer due to a big difference of coefficient of thermal expansion between the substrate and the insulative polymer, thereby affecting the yield rate of the fabrication of IC substrate. Further, because the polymer filling procedure is performed under the open air, air may be not fully expelled out of the filling space of the substrate during polymer filling process, resulting in oxidation of the finished IC substrate.

### SUMMARY OF THE INVENTION

The present invention has been accomplished under the circumstances in view. It is one objective of the present invention to provide an IC substrate fabrication method, which prevents curving of the substrate during filling of insulative polymer, improving the yield rate of the fabrication of IC substrate.

It is another objective of the present invention to provide an IC substrate fabrication method, which eliminates formation of air bubbles in the insulative polymer, prolonging the service life of the IC substrate.

According to one aspect of the present invention, the IC substrate fabrication method comprises the steps of: a) preparing a substrate having a front side and a back side and half-etching the substrate to form a filling space in the front side of the substrate subject to a predetermined depth and area, b) putting the substrate thus obtained from step a) in a cavity of a mold and employing a polymer filling and mold pressing procedure to fill up the filling space with an insulative polymer, and c) removing the substrate from the mold and half-etching the back side of the substrate body so as to obtain an IC substrate.

According to another aspect of the present invention, the step b) comprises a sub step of drawing air out of the mold, preventing formation of air bubbles in the insulative polymer.

### BRIEF DESCRIPTION OF THE DRAWINGS

FIG. 1 is a flow chart of an IC substrate fabrication method according to the present invention.

FIG. 2 is a top plain view of a substrate for IC substrate according to the present invention.

FIG. 3 is a front view of the substrate after half etching on the front side according to the present invention.

FIG. 4 is a top view of the substrate after half etching on the front side according to the present invention.

FIG. 5 is a schematic drawing showing step b) of the IC substrate fabrication method according to the present invention.

FIG. 6 is a schematic drawing showing the filling space of the substrate filled up with an insulative polymer according to the present invention.

FIG. 7 is a front view of the substrate after half etching on the back side according to the present invention.

FIG. 8 is a schematic drawing showing step b) of an alternate form of the IC substrate fabrication method according to the present invention.

### DETAILED DESCRIPTION OF THE INVENTION

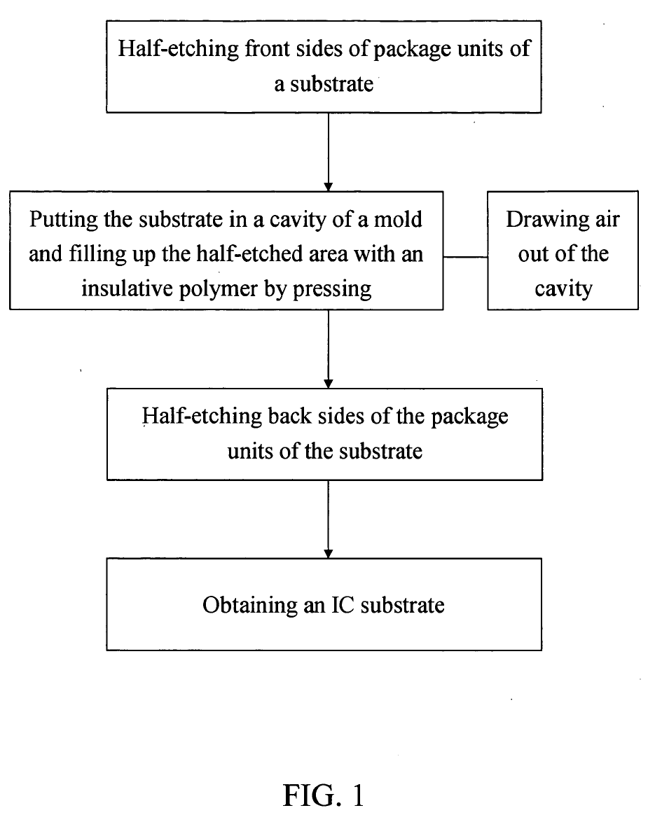

Referring to FIG. 1, an IC substrate fabrication method in accordance with the present invention includes the following three steps:

a) half-etching the front side of each package unit on the substrate body;

b) putting the substrate in the cavity of a mold and covering the half-etched area with an insulative polymer by pressing; and

c) half-etching the back side of the substrate body.

It is suggested to employ a vacuum process to draw air away from the cavity of the mold before the polymer filling and pressing process.

Referring to FIG. 2, the IC substrate comprises a substrate body 11 and a plurality of package blocks 12 at the substrate body 11. Each package block 12 is formed of an array of package units 13.

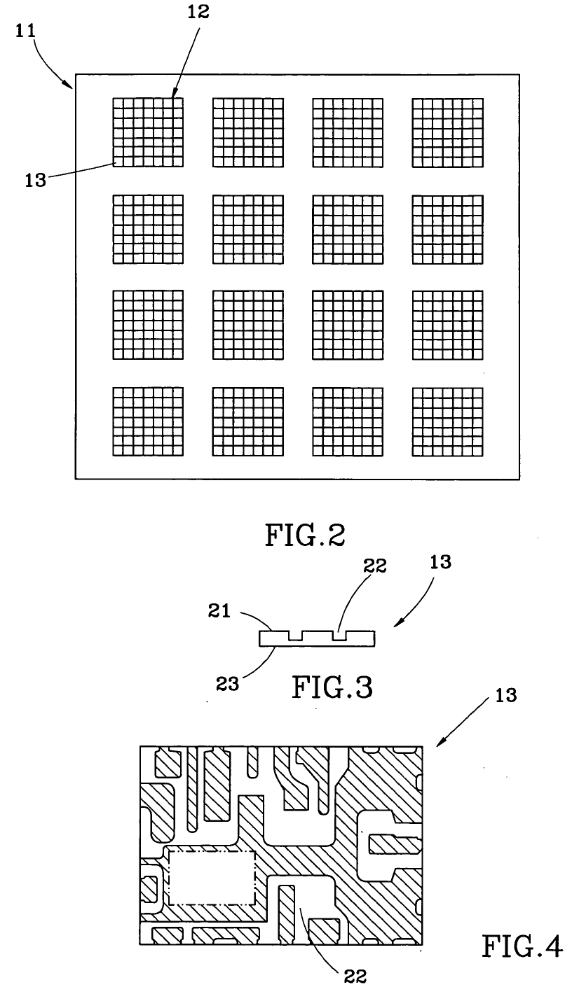

FIGS. 3-7 show an example of the fabrication of an IC substrate according to the first preferred embodiment of the present invention. The fabrication procedure includes the steps of:

a) half-etching a rectangular substrate to form a filling space 22 at each of the front sides 21 of the package units 13 subject to a predetermined depth and area (see FIGS. 3 and 4);

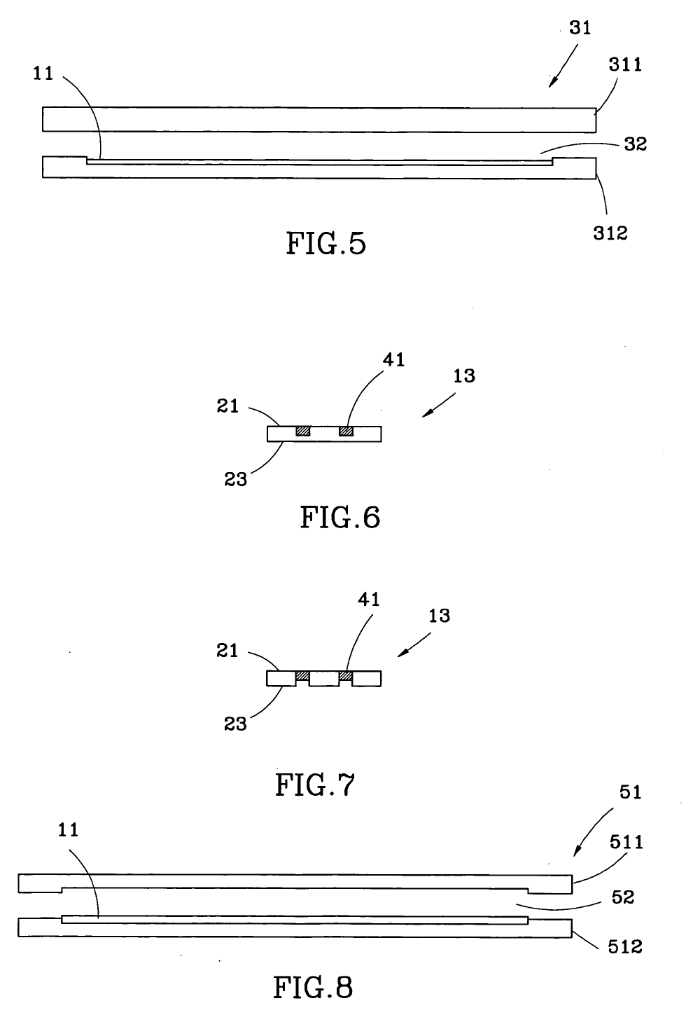

b) putting the half-etched rectangular substrate 11 in a mold 31, which comprises a rectangular bottom die 312 and a flat rectangular upper die 311 covered to the top side of the rectangular bottom die 312 and defined with the recessed center area of the rectangular bottom die 312 a cavity 32 for receiving the half-etched rectangular substrate (see FIG. 5), and then drawing air out of the cavity 32 of the mold 31, and then injecting a fluid of insulative polymer 41 into the cavity 32 of the mold 31 and pressing the rectangular upper die 311 on the rectangular bottom die 312 to have the filling space 22 be filled up with the insulative polymer 41 (see FIG. 6);

c) removing the substrate 11 from the mold 31, and then half-etching the back sides 23 of the package units 13 corresponding to the etched area at the front side 21 of the package units 13 (see FIG. 7), leaving the insulative polymer 41 to form an insulative shield.

In the aforesaid step b), the selected insulative polymer has a coefficient of thermal expansion close to the substrate 11 so that the substrate 11 does not curve significantly during the pressing operation after filling of the insulative polymer. The action of drawing air out of the cavity 32 of the mold 31 prevents the production of air bubbles in the insulative polymer.

According to a second preferred embodiment of the present invention, the mold 51 used comprising a rectangular flat bottom die 512 that has a recessed top center area, and a rectangular upper die 511 that has a recessed bottom center area, as shown in FIG. 8.

As indicated above, the invention provides an IC substrate fabrication method, which eliminates the substrate curving problem and the production of air bubbles in the polymer filling space during filling of polymer.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A method of making an IC substrate, comprising the steps of:
a) preparing a substrate having a front side and a back side and half-etching said substrate to form a filling space in the front side of said substrate subject to a predetermined depth and area;
b) putting the substrate thus obtained from step a) in a cavity of a mold and employing a polymer filling and mold pressing procedure to fill up said filling space with an insulative polymer; and
c) removing said substrate from said mold and half-etching the back side of the substrate body so as to obtain an IC substrate.

2. The method as claimed in claim 1, wherein said step (b) comprises a sub step of drawing air out of said mold.

3. The method as claimed in claim 1, wherein said mold comprises a bottom die, and an upper die closed on said bottom die and defining with said bottom die said cavity.
